(19) United States
(12) Patent Application Publication
(10) Pub. No.: US 2025/0200410 A1
(43) Pub. Date: Jun. 19, 2025

(54) PERFORMANCE OF READOUT AND RESET OF FLUXONIUM QUBITS

(71) Applicant: Amazon Technologies, Inc., Seattle, WA (US)

(72) Inventors: Emma Louise Rosenfeld, Los Angeles, CA (US); Oskar Jon Painter, Sierra Madre, CA (US); Hanho Lee, Alhambra, CA (US)

(73) Assignee: Amazon Technologies, Inc., Seattle, WA (US)

(21) Appl. No.: 18/515,685

(22) Filed: Nov. 21, 2023

(51) Int. Cl. G06N 10/40; G06N 10/20

(52) U.S. Cl. CPC G06N 10/40; G06N 10/20

(57) ABSTRACT

Techniques for performing readout and reset of fluxonium qubits are disclosed. When fluxonium hardware components are coupled to a quantum metamaterial through a readout resonator, said components may be dispersively coupled such that a quantum state of the corresponding fluxonium qubit is read out through the quantum metamaterial, and then the state of the fluxonium qubit is subsequently reset in order to proceed with a quantum computation to be performed. Alternatively, when fluxonium hardware components are coupled directly to a quantum metamaterial, a quantum state of a fluxonium qubit is read out using resonance fluorescence, and then may be subsequently reset back to its ground state, also using resonance fluorescence. A width of a passband of the quantum metamaterial, along with frequencies of the control sequences used, may be tuned such that either readout or reset is selectively activated.

### BACKGROUND

Quantum computing utilizes the laws of quantum physics to process information. Quantum physics is a theory that describes the behavior of reality at the fundamental level. It is currently the only physical theory that is capable of consistently predicting the behavior of microscopic quantum objects like photons, molecules, atoms, and electrons.

A quantum computer is a device that utilizes quantum physics to allow one to write, store, process and read out information encoded in quantum states, e.g., the states of quantum objects. A quantum object is a physical object that behaves according to the laws of quantum physics. The state of a physical object is a description of the object at a given time.

In quantum physics, the state of a two-level quantum system, or simply, a qubit, is a list of two complex numbers whose squares sum up to one. Each of the two numbers is called an amplitude, or quasi-probability, and their squared absolute values are probabilities that a measurement of the qubit results in zero or one. A fundamental and counterintuitive difference between a probabilistic bit (e.g., a classical zero or one bit) and the qubit is that a probabilistic bit represents a lack of information about a two-level classical system, while a qubit contains maximal information about a two-level quantum system.

Quantum computers are based on such quantum bits (qubits), which may experience the phenomena of “superposition” and “entanglement.” Superposition allows a quantum system to be in multiple states at the same time. For example, whereas a classical computer is based on bits that are either zero or one, a qubit may be both zero and one at the same time, with different probabilities assigned to zero and one. Entanglement is a strong correlation between quantum systems, such that the quantum systems are inextricably linked even if separated by great distances.

A quantum algorithm comprises a reversible transformation acting on qubits in a desired and controlled way, followed by a measurement on one or multiple qubits. For example, if a system has two qubits, a transformation may modify four numbers; with three qubits this becomes eight numbers, and so on. As such, a quantum algorithm acts on a list of numbers exponentially large as dictated by the number of qubits. To implement a transform, the transform may be decomposed into small operations acting on a single qubit, or a pair of qubits, as an example. Such small operations may be called quantum gates and a specific arrangement of the quantum gates implements a quantum circuit.

There are different types of qubits that may be used in quantum computers, each having different advantages and disadvantages. For example, some quantum computers may include qubits built from superconductors, trapped ions, semiconductors, photonics, etc. Each may experience different levels of interference, errors and decoherence. Also, some may be more useful for generating particular types of quantum circuits or quantum algorithms, while others may be more useful for generating other types of quantum circuits or quantum algorithms. Also, costs, run-times, error rates, availability, etc. may vary across quantum computing technologies.

### BRIEF DESCRIPTION OF THE DRAWINGS

FIG. 1 illustrates a hardware layout of a quantum hardware device that is configured to perform readout of a fluxonium qubit by dispersively coupling hardware components that implement a fluxonium qubit to a readout resonator, which, in turn, is coupled to a quantum metamaterial, according to some embodiments.

FIG. 2 illustrates steps that are applied in order to perform a given quantum circuit between two fluxonium qubits, wherein the steps include at least a reset (e.g., initialization) step of the fluxonium qubits, performance of one or more quantum gates between the two fluxonium qubits, and performance of readout step of quantum superposition states of the two fluxonium qubits, according to some embodiments.

FIG. 3A illustrates an energy state diagram for a given fluxonium, wherein computational basis states of the fluxonium qubit have been logically mapped to a ground state and a first excited state of the fluxonium, according to some embodiments.

FIG. 3B illustrates frequencies at which the fluxonium illustrated in FIG. 3A may be driven in order to drive various transitions between energy states of the fluxonium, according to some embodiments.

FIGS. 4A and 4B illustrate a control sequence, in the frequency and time domains, respectively, for performing readout of a fluxonium qubit using a hardware layout such as that which is shown in FIG. 1, according to some embodiments.

FIG. 5 illustrates another hardware layout of a quantum hardware device that is configured to perform readout of a fluxonium qubit by dispersively coupling hardware components that implement a fluxonium qubit to a readout resonator, which, in turn, is coupled to a Purcell filter, which, in turn, is coupled to a quantum metamaterial, according to some embodiments.

FIG. 6 illustrates a process of performing readout of a quantum superposition state of a fluxonium qubit using dispersive coupling, according to some embodiments.

FIG. 7 illustrates a hardware layout of a quantum hardware device that is configured to perform both fluorescent readout of a fluxonium qubit and fluorescent reset of the fluxonium qubit by coupling hardware components that implement a fluxonium qubit to a quantum metamaterial, according to some embodiments.

FIGS. 8A and 8B illustrate a control sequence, in the frequency and time domains, respectively, for performing readout of a fluxonium qubit using a hardware layout such as that which is shown in FIG. 7, according to some embodiments.

FIGS. 9A and 9B illustrate a first control sequence, in the frequency and time domains, respectively, for performing reset of a fluxonium qubit using a hardware layout such as that which is shown in FIG. 7, according to some embodiments.

FIGS. 10A and 10B illustrate a second control sequence, in the frequency and time domains, respectively, for performing reset of a fluxonium qubit using a hardware layout such as that which is shown in FIG. 7, according to some embodiments.

FIGS. 11A and 11B illustrate a third control sequence, in the frequency and time domains, respectively, for performing reset of a fluxonium qubit using a hardware layout such as that which is shown in FIG. 7, according to some embodiments.

FIGS. 12A and 12B illustrate a fourth control sequence, in the frequency and time domains, respectively, for performing reset of a fluxonium qubit using a hardware layout such as that which is shown in FIG. 7, according to some embodiments.

FIG. 13 illustrates a process of performing fluorescent readout and reset of a fluxonium qubit, according to some embodiments.

FIG. 14 is a block diagram illustrating an example quantum hardware device that may be configured to execute quantum gates between fluxonium qubits, and to perform readout and reset steps in between execution of said quantum gates, according to some embodiments.

FIG. 15 is a block diagram illustrating an example classical computing device that may be used in at least some embodiments.

While embodiments are described herein by way of example for several embodiments and illustrative drawings, those skilled in the art will recognize that embodiments are not limited to the embodiments or drawings described. It should be understood, that the drawings and detailed description thereto are not intended to limit embodiments to the particular form disclosed, but on the contrary, the intention is to cover all modifications, equivalents and alternatives falling within the spirit and scope as defined by the appended claims. The headings used herein are for organizational purposes only and are not meant to be used to limit the scope of the description or the claims. As used throughout this application, the word “may” is used in a permissive sense (i.e., meaning having the potential to), rather than the mandatory sense (i.e., meaning must). Similarly, the words “include,” “including,” and “includes” mean including, but not limited to. When used in the claims, the term “or” is used as an inclusive or and not as an exclusive or. For example, the phrase “at least one of x, y, or z” means any one of x, y, and z, as well as any combination thereof.

### DETAILED DESCRIPTION

The present disclosure relates to methods and apparatus for performing readout of fluxonium qubits, and to performing reset (which may also be referred to herein as “initialization” and/or “reinitialization”) of fluxonium qubits. In embodiments described herein, fluxonium hardware components that may be used to implement a fluxonium qubit are coupled to a quantum metamaterial using various quantum hardware configurations such that readout and reset steps may be performed rapidly and with high fidelity.

Within the noisy intermediate-scale quantum (NISQ) hardware regime, quantum error correction and/or mitigation techniques are faced with the difficult task of developing methods for correcting single and multi-qubit errors, logical errors, and/or additional quantum processing unit (QPU) specific qubit coherence time and/or lifetime concerns, crosstalk noise levels, etc. Further complexity may be incurred if quantum readout devices that are configured to perform readout to obtain quantum states of qubits of a given QPU at different intervals during quantum computation cannot overcome the Purcell decay, and/or cannot perform the readout sufficiently quickly in order to ensure that a time to perform the readout measurements is far less than expected coherence times and/or lifetimes of qubits involved within the given quantum computation. A risk of further error propagation exists when a qubit is not properly reset into an arbitrary quantum state (e.g., the ground state) prior to performance of a quantum gate.

Therefore, as customers that are utilizing such quantum computing resources may be concerned with repeatability, reliability, and efficiency of quantum task executions, providing quantum readout devices that overcome the Purcell decay rate and ensure rapid and accurate delivery of readout results to classical measurement devices is of importance. As current quantum error correction and/or mitigation techniques have limited numbers of errors that they may compensate for within a given quantum task, ensuring that further variation and/or uncertainty is not also propagated during quantum readout processes allows for such quantum error correction and/or mitigation techniques to have a larger bandwidth to correct for errors that occurred during execution of various quantum gates of the given quantum task and not at the readout steps. Similarly, a successful reset of fluxonium qubits, subsequent to performing such a readout step, ensures that a next stage in the given quantum computation (e.g., one or more additional quantum gates between fluxonium qubits) may proceed without error propagation from the previous stage. In some embodiments, performance characteristics of quantum hardware devices that enable performance of both readout and reset of fluxonium qubits may be defined by fidelity and by speed. Such performance characteristics have previously been typically seen as a tradeoff. However, by coupling fluxonium qubits to a quantum metamaterial, using techniques and architectures described herein, both higher fidelity and faster readout and reset may be provided to customers that are utilizing such quantum computing resources.

In some embodiments, fluxonium hardware components that may be used to implement a fluxonium qubit may be dispersively coupled to a readout resonator, which in turn is coupled to a quantum metamaterial, in order to perform readout. In other embodiments, fluxonium hardware components that may be used to implement a fluxonium qubit may be directly coupled to a quantum metamaterial in order to perform readout and reset using resonance fluorescence. Depending upon design constraints of a given implementation of a quantum computer, either architecture may be selected and subsequently fabricated in order to ensure higher fidelity and faster readout and reset for fluxonium-qubit-based quantum computing architectures.

In addition, as related to the description herein, it may be understood that quantum hardware, such as quantum hardware devices, may be used to implement quantum computers, and/or various components of quantum computers (e.g., quantum processing units/cores, routing spaces, magic state distillation factories, other components used to perform logical quantum computations, etc.). For example, a given quantum hardware device may resemble “building blocks” of a quantum computer, such as a grid (e.g., a one-dimensional grid, a two-dimensional grid, etc.) of qubits that may be initialized in various ways in order to form various components of a quantum computer, such as topological quantum codes. Quantum hardware devices may be further configured such that single qubit gates, multi-qubit gates, and/or other operations of quantum circuits may be performed between qubits of the quantum hardware devices (according to a given physical qubit connectivity graph of the quantum hardware device which details which physical qubits are connected to respective other physical qubits via edges). Quantum hardware devices may also comprise and/or be connected to various control devices (e.g., microwave pulse generators, devices for temperature, magnetic, and/or other environmental controls pertaining to local environments of the physical qubits, etc.) that may be used to maintain and/or transform various properties of the qubits and/or other physical components of a given quantum computer.

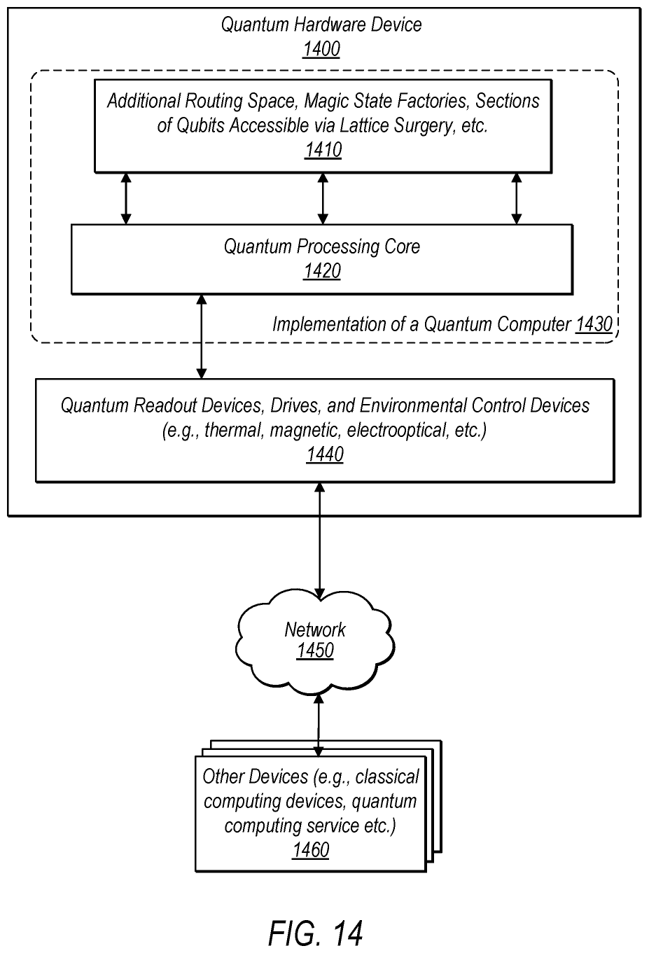

Moreover, as related to the description herein, a qubit may refer to both a logical bit (e.g., a one or a zero with some probability) and to one or more physical components used to construct the given qubit based, at least in part, on the type of qubit technology being applied. For example, a fluxonium qubit may be constructed using at least a superconducting material and a non-superconducting material in which the non-superconducting material is located in between sections of superconducting material (see also description pertaining to fluxonium hardware components herein). With regard to this understanding, it should also be understood that quantum hardware may therefore be used to implement physical qubits, in ways such as those as described above, that may again be combined in various ways to implement one or more logical qubits such that logical quantum operations may be performed using said physical elements of said quantum hardware. Further examples of interactions between hardware layouts of quantum hardware devices and associated classical measurement and control devices are discussed with regard to at least FIG. 14 herein.

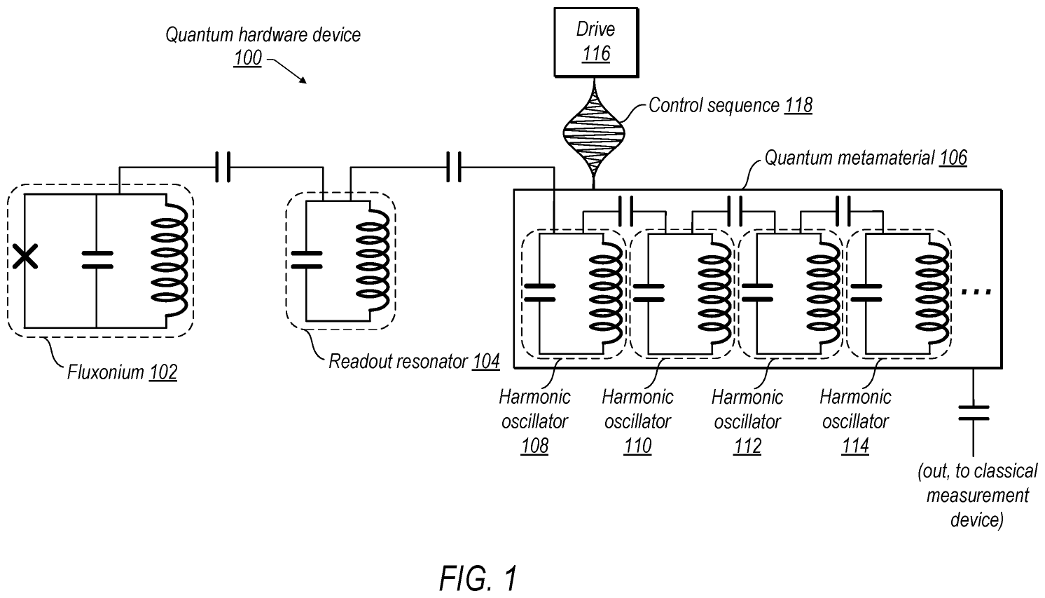

FIG. 1 illustrates a hardware layout of a quantum hardware device that is configured to perform readout of a fluxonium qubit by dispersively coupling hardware components that implement a fluxonium qubit to a readout resonator, which, in turn, is coupled to a quantum metamaterial, according to some embodiments.

In some embodiments, a set of fluxonium hardware components may be arranged in parallel, as shown in FIG. 1, in order to implement a fluxonium qubit. For example, fluxonium 102 includes an inductor, a capacitor, and a Josephson junction arranged in parallel with one another. In some embodiments, a fluxonium, such as fluxonium 102, may be defined by three degrees of freedom in terms of circuit parameters: energy associated with the capacitor (E_{cap}), energy associated with the Josephson junction (Eⱼⱼ), and energy associated with the inductive shunt (E_{L}) of the given fluxonium. Moreover, control over such circuit parameters allows for a logical mapping to two given energy states of an energy state diagram, enabled by a hardware configuration of fluxonium 102, to be defined as a corresponding fluxonium qubit, along with allowing the qubit's frequency, the expected lifetime of the qubit's energy (t₁), and the dephasing time (t₂) of the qubit to be tuned and, according to some embodiments, tuned independently from one another.

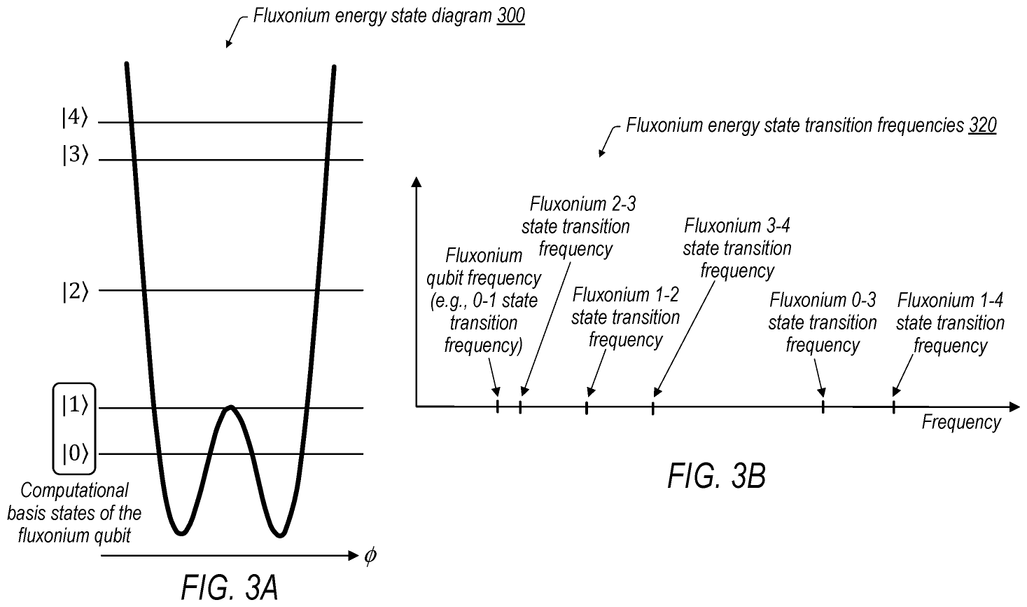

As additionally explained herein with regard to fluxonium energy state diagram 300 in FIG. 3, computational basis states of a given fluxonium qubit that may be implemented using hardware components of quantum hardware device 100 may be logically mapped as |0> and |1>, and may correspond to a ground state and a first excited state of energy states of an energy state diagram for fluxonium.

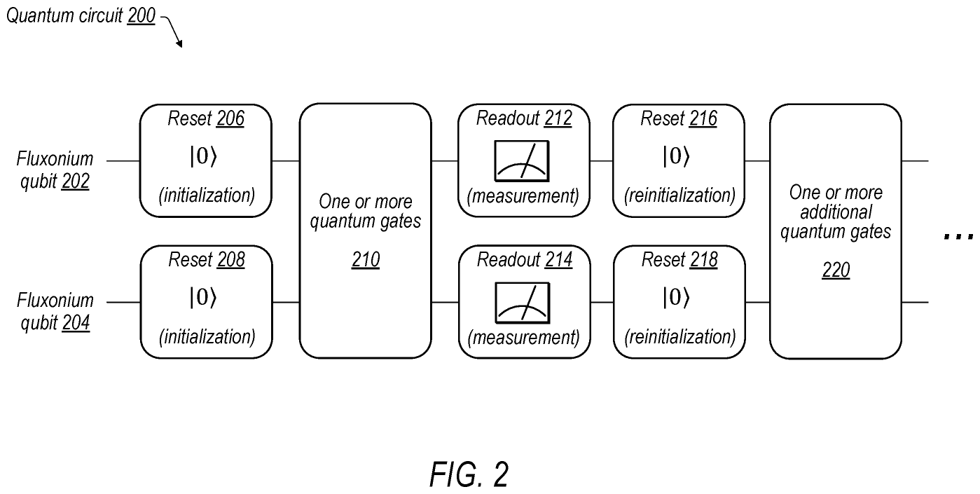

In some embodiments, a given configuration of quantum hardware components, such as that which is shown in FIG. 1, may be used to enable dispersive coupling between fluxonium 102, readout resonator 104, and quantum metamaterial 106. It may be understood that, due to a hardwiring of capacitive coupling between said respective components, the dispersive coupling may be assumed to be “on-going” throughout the performance of various quantum gates, and throughout the performance of readout, etc. (see also various steps within a performance for quantum circuit 200, as additionally described with regard to FIG. 2 herein).

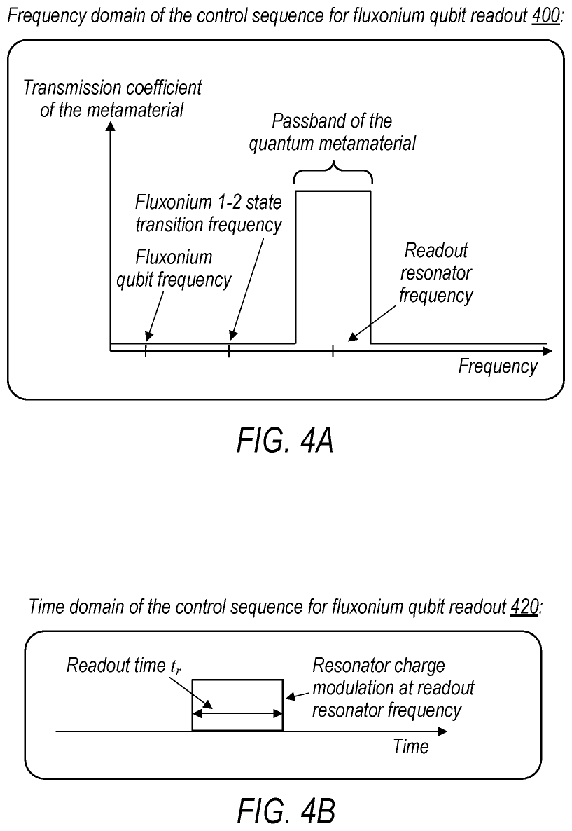

Therefore, in order to extract information about a quantum state of a fluxonium qubit at various intervals during a given quantum computation (see also description herein pertaining to an example quantum circuit 200 in FIG. 2), readout of a fluxonium qubit, implemented using fluxonium hardware components of fluxonium 102, may be performed by emitting a control sequence that causes a signal, corresponding to the information about the quantum state, to be transmitted through readout resonator 104, and subsequently through quantum metamaterial 106, wherein the signal may then be read out by a classical measurement device. As additionally illustrated in FIGS. 4A and 4B herein, by emitting a control sequence having a frequency corresponding to a resonance frequency of readout resonator 104, the readout resonator may be driven from its ground state to its excited state. Such an addition of energy into a system described by the hardware layout shown in FIG. 1 then causes said energy to decay into quantum metamaterial 106, allowing the information about the quantum state to be transmitted, indirectly, from the fluxonium qubit and through to quantum metamaterial 106, according to some embodiments. Furthermore, the dispersive coupling further defines a frequency shift that is conditional upon the given quantum state of the fluxonium qubit at a time of readout, therefore allowing the classical measurement device to determine which quantum state of the two possible quantum states of the fluxonium qubit has been transmitted during performance of the readout.

In some embodiments, quantum metamaterial 106 may act as a transmission line when coupled to fluxonium 102 via readout resonator 104 such that the signal is rapidly propagated through respective harmonic oscillators of quantum metamaterial 106 and out towards a classical measurement device. As shown in FIG. 1, quantum metamaterial 106 includes at least harmonic oscillators 108, 110, 112, and 114. It may be understood that additional implementations of quantum metamaterial 106 may include fewer harmonic oscillators or more harmonic oscillators than a number depicted in FIG. 1, and that a number of harmonic oscillators included within quantum metamaterial 106 may determine, at least in part, a width of a passband of quantum metamaterial 106, in addition to various other circuit parameters of an overall hardware configuration of quantum hardware device 100. Moreover, readout resonator 104 is shown as being directly coupled to harmonic oscillator 108 in FIG. 1. However, in other embodiments, readout resonator 104 may instead be directly coupled to harmonic oscillator 110, 112, or 114, etc.

Furthermore, quantum metamaterial 106 may additionally be referred to herein as acting as a “bus,” since respective ones of harmonic oscillators 108, 110, 112, and 114 are capacitively coupled to one another in a configuration such as that which is shown in FIG. 1. Additional references used herein with regard to a quantum metamaterial having “unit cells” and/or “taper cells” should also be understood as cells that are implemented using harmonic oscillators, such as those shown in FIG. 1. In some embodiments, taper cells may be physically placed at respective ends of a given harmonic oscillator array within the quantum metamaterial. For example, referring to that which is shown in FIG. 1, harmonic oscillators 108 and 114 within quantum metamaterial 106 may be defined as taper cells in some embodiments in which quantum metamaterial 106 includes four total harmonic oscillators. Furthermore, such taper cells may be configured to reduce an impedance mismatch (Z₀=50Ω) to external ports (e.g., such as that which is labeled as “out, to classical measurement device” in FIG. 1) at frequencies within a passband of the given quantum metamaterial. Continuing with the reference to that which is shown in FIG. 1, harmonic oscillators 110 and 112 within quantum metamaterial 106 may then be defined as unit cells.

In some embodiments, drive 116 may resemble a microwave pulse generator that is configured to emit a microwave pulse having a frequency corresponding to the resonance frequency of readout resonator 104. Drive 116 may be further configured to receive drive control instructions from a classical computing device, such as classical computing device 1500, wherein the drive control instructions may include information such as duration of the pulse to be emitted, frequency of the pulse to be emitted, timing of when to emit the pulse within an overall execution of a given quantum computation, etc.

In some embodiments, in order to perform readout of a fluxonium qubit implemented using fluxonium 102, the following combination of values for circuit parameters of quantum hardware device 100 may be used. Degrees of freedom of Fluxonium 102 may be configured such that Eⱼⱼ=7 GHZ, E_{cap}=1.98 GHZ, and E_{L}=0.3 GHZ. Fluxonium 102 may then be capacitively coupled to readout resonator 104 with a capacitive coupling strength of 1.7 fF. Readout resonator 104 may be configured such that a resonance frequency of readout resonator 104 is 8.494 GHZ, and such that it has an impedance of 115Ω. Readout resonator 104 may then be capacitively coupled to quantum metamaterial 106 with a capacitive coupling strength of 5.0 fF. Quantum metamaterial 106 may then be configured to have two taper cells, six unit cells, a capacitive coupling strength of 10 fF, and an impedance of 115Ω. However, it should be understood that the above-mentioned combination of parameters may represent a given implementation of quantum hardware device 100, and that other implementations of quantum hardware device 100 that are configured to have different combinations of values for circuit parameters, but that still allow components of quantum hardware device 100 to be dispersively coupled and to perform readout, are meant to also be included in the discussion herein.

In some embodiments, in order to configure dispersive coupling between respective components of quantum hardware device 100, fluxonium 102 may be capacitively coupled to readout resonator 104, and readout resonator 104 may be capacitively coupled to quantum metamaterial 106, as shown in FIG. 1. However, in some embodiments, inductive coupling may be used in order to configure dispersive coupling between the respective components of quantum hardware device 100.

Furthermore, it should be understood that, in some embodiments, fluxonium 102 may be connected to one or more other sets of fluxonium hardware components of a larger-scale quantum hardware device that implement respective and additional fluxonium qubits. For example, fluxonium 102 may be implemented within quantum processing core 1420, as shown in FIG. 14, wherein readout resonator 104, quantum metamaterial 106, and drive 116 may then be implemented within quantum readout devices 1440, as additionally shown in FIG. 14. Moreover, it should be understood that a grounding of one or more of the hardware components of quantum hardware device 100 may also be required, and is meant to be encompassed within discussion of a given larger architecture design implementation that includes quantum hardware device 100, such as that which is described with regard to implementation of a quantum computer 1430.

In some embodiments, a configuration such as that which is shown with regard to quantum hardware device 100 in FIG. 1 may additionally be used to perform reset of a fluxonium qubit implemented using fluxonium 102. In some embodiments, such a reset may occur actively through a sideband between the fluxonium qubit and readout resonator 104 (e.g., a sideband corresponding to a frequency that is not a resonance frequency of readout resonator 104).

FIG. 2 illustrates steps that are applied in order to perform a given quantum circuit between two fluxonium qubits, wherein the steps include at least a reset (e.g., initialization) step of the fluxonium qubits, performance of one or more quantum gates between the two fluxonium qubits, and performance of readout step of quantum superposition states of the two fluxonium qubits, according to some embodiments.

As introduced above, performance of readout of fluxonium qubits, implemented using fluxonium hardware components described herein, may take place after one or more quantum gates have been performed on such fluxonium qubits. In some embodiments, performance of a quantum gate on a fluxonium qubit may influence a quantum state of the fluxonium qubit with respect to how the quantum state was initialized during reset, prior to performance of the quantum gate, due to a logical quantum operation that is being performed on the fluxonium qubit for a duration of the gate. Therefore, in order to extract quantum states of such fluxonium qubits following performance of the gate, readout may be performed using a hardware layout such as that which is depicted in quantum hardware device 100 (in addition to hardware layouts which are additionally described below with regard to quantum hardware device 500 and quantum hardware device 700).

As shown in FIG. 2, quantum circuit 200 involves two fluxonium qubits, such as fluxonium qubit 202 and fluxonium qubit 204. A first timestep of quantum circuit 200 may resemble reset 206 and 208, wherein fluxonium qubits 202 and 204 are initialized into some arbitrary quantum state, such as the ground state. In some embodiments, the ground state may be represented by |0>, as additionally shown in FIG. 3A with regard to fluxonium energy state diagram 300. Furthermore, reset 206 and 208 may occur simultaneously or sequentially, depending upon various embodiments of quantum circuit execution instructions provided to a quantum hardware device and used for execution of quantum circuit 200.

Following initialization of fluxonium qubits 202 and 204, one or more quantum gates 210 may be performed using fluxonium qubits 202 and 204. In some embodiments, one or more quantum gates 210 may include a two-qubit quantum gate that is performed using both fluxonium qubits 202 and 204 (e.g., a CZ gate, a CX gate, a SWAP gate, etc.). In other embodiments, one or more quantum gates 210 may include two separate single-qubit gates that are respectively performed using fluxonium qubits 202 and 204 (e.g., Pauli-X, -Y, or -Z gates, a Hadamard gate, a Phase gate, etc.). In yet other embodiments, one or more quantum gates 210 may include combinations of single and/or multi-qubit quantum gates that are performed using fluxonium qubits 202 and 204. Furthermore, single and/or multi-qubit quantum gates that are performed during a block represented by one or more quantum gates 210 resemble logical quantum operations that may influence quantum states of fluxonium qubits 202 and 204, and, therefore, a next timestep of quantum circuit 200 may involve performance of readout.

As shown in FIG. 2, following performance of one or more quantum gates 210, a readout step 212 of fluxonium qubit 202 and a readout step 214 of fluxonium qubit 204 may be performed. Readouts 212 and 214 may be performed using a quantum hardware device such as quantum hardware device 100, and may be performed using a control sequence such as that which is additionally described with regard to FIGS. 4A and 4B herein. Furthermore, reset 206 and 208 may occur simultaneously or sequentially, depending upon various embodiments of quantum circuit execution instructions provided to a quantum hardware device for execution of quantum circuit 200. In some embodiments, such a readout step may resemble repeated parity measurements, or other quantum non-demolition (QND) measurements which allow for a quantum state to be read out indirectly and without collapsing said state.

Following performance of readouts 212 and 214, fluxonium qubits 202 and 204 may be reinitialized into the ground state during a next timestep, as shown in FIG. 2 with regard to resets 216 and 218. As additionally described above, resets 216 and 218 may occur simultaneously or sequentially. Furthermore, as depicted in FIG. 2 with one or more additional quantum gates 220 and the subsequent ellipses, quantum circuit 200 may include two or more rounds of quantum gates that are performed using fluxoniums 202 and 204. In some embodiments, following respective ones of the rounds of quantum gates between fluxoniums 202 and 204, both readout and reset may be performed using techniques described herein.

Furthermore, it may be understood that a given configuration of quantum circuit 200 shown in FIG. 2, which includes performance of multiple sets of quantum gates between two fluxonium qubits, is meant to be illustrative in nature. Additional embodiments of quantum circuits that involve one fluxonium qubit, or more than two fluxonium qubits, are also meant to be encompassed in the discussion herein, and may similarly apply to methods for performing readout and reset using quantum hardware device architectures described herein.

FIG. 3A illustrates an energy state diagram for a given fluxonium, wherein computational basis states of the fluxonium qubit have been logically mapped to a ground state and a first excited state of the fluxonium, according to some embodiments.

As shown in FIG. 3A, fluxonium hardware components, such as those shown in fluxonium 102 in FIG. 1, may be configured such that energy states of fluxonium energy state diagram 300 are enabled. It may be understood that, while a ground state (|0>), a first excited state (|1>), a second excited state (|2>), a third excited state (|3>), and a fourth excited state (|4>) are illustrated in FIG. 3A, additional higher energy states, enabled by the configuration of fluxonium hardware components, may also be encompassed within a discussion of fluxonium energy state diagram 300 herein.

As additionally shown in FIG. 3A, two energy states, enabled by a given configuration of fluxonium hardware components, may be logically mapped to computational basis states of a corresponding fluxonium qubit. For example, computational basis states may be logically mapped to a ground state (|0>) and a first excited state (|1>) of energy states of fluxonium energy state diagram 300.

FIG. 3B illustrates frequencies at which the fluxonium illustrated in FIG. 3A may be driven in order to drive various transitions between energy states of the fluxonium, according to some embodiments.

As shown in a plot of fluxonium energy state transition frequencies 320, a frequency that may be used to excite a particle, such as a photon, into a given energy state from some other energy state of the energy states depicted in fluxonium energy state diagram 300 may correspond to frequencies incrementally shown along the x-axis in FIG. 3B, according to some embodiments. Such frequencies that cause various excitations between energy states may also be referred to as “transition frequencies” herein.

For example, fluxonium qubit frequency may refer to a frequency that would be needed to drive a photon from the ground state to the first excited state, or vice versa. Fluxonium 2-3 state transition frequency may refer to a frequency that would be needed to drive a photon from the second excited state to the third excited state, or vice versa. Fluxonium 1-2 state transition frequency may refer to a frequency that would be needed to drive a photon from the first excited state to the second excited state, or vice versa. Fluxonium 3-4 state transition frequency may refer to a frequency that would be needed to drive a photon from the third excited state to the fourth excited state, or vice versa. Fluxonium 0-3 state transition frequency may refer to a frequency that would be needed to drive a photon from the ground state to the third excited state, or vice versa. Fluxonium 1-4 state transition frequency may refer to a frequency that would be needed to drive a photon from the first excited state to the fourth excited state, or vice versa. Using methods and techniques described herein, such state transition frequencies may be used within control sequences in order to perform readout of fluxonium qubits and/or perform reset steps of fluxonium qubits.

FIGS. 4A and 4B illustrate a control sequence, in the frequency and time domains, respectively, for performing readout of a fluxonium qubit using a hardware layout such as that which is shown in FIG. 1, according to some embodiments.

In some embodiments, a control sequence, such as control sequence 118, which is configured to be emitted by drive 116 and cause a non-destructive measurement of a quantum state to be transmitted from corresponding fluxonium hardware components (e.g., fluxonium 102), through readout resonator 104, and into quantum metamaterial 106 for read out, may resemble depictions in frequency domain 400 and time domain 420.

As shown in frequency domain 400, circuit parameters of quantum hardware device 100 are configured such that a passband of quantum metamaterial 106 includes a range of frequencies that is higher than both the fluxonium qubit frequency and the fluxonium 1-2 state transition frequency (see also description pertaining to fluxonium energy state transition frequencies 320 herein). Furthermore, circuit parameters of quantum hardware device 100 are additionally configured such that the resonance frequency of readout resonator 104 is within a range of frequencies that define the passband of quantum metamaterial 106. As such, when control sequence 118 is emitted, readout resonator 104 is driven at its resonance frequency, and, since this resonance frequency is configured to be within the passband of quantum metamaterial 106, information pertaining to a quantum state of the fluxonium qubit implemented using fluxonium 102 is dispersively transmitted through readout resonator 104, and then through quantum metamaterial 106 towards a classical measurement device.

Furthermore, as the fluxonium qubit frequency is configured to reside outside of the passband of the quantum metamaterial, energy held within the energy states corresponding to the computational basis states of the fluxonium qubit cannot decay through the readout resonator to the quantum metamaterial, providing protection of the quantum state of the fluxonium qubit, even during performance of readout. In some embodiments, the fluxonium 1-2 state transition frequency may be configured to also reside outside of the passband of the quantum metamaterial, as this particular transition frequency may be used during performance of some quantum gates that are sequentially before and/or after such readout, and therefore should also remain isolated from the passband such that energy at this frequency does not decay into the quantum metamaterial.

In some embodiments, a width of the passband of the quantum metamaterial shown in FIG. 4A may be approximately 1-2 GHz, the fluxonium qubit frequency may be approximately 254 MHZ, the fluxonium 1-2 state transition frequency may be approximately 7.13 GHZ, and the resonance frequency of the readout resonator may be approximately 8.494 GHz.

As further depicted with regard to time domain 420, control sequence 118 may have a duration of time defined by readout time tᵣ. In some embodiments, readout time tᵣ may be used to define an amount of time during which a charge modulation of readout resonator 104 is occurring at a driving frequency corresponding to the resonance frequency of readout resonator 104. Readout time tᵣ may be approximately 10 ns, according to some embodiments.

In some embodiments, performance characteristics of control sequence 118 may be defined by qubit-readout dispersive coupling parameter χ and by a readout bandwidth parameter κ. In order to achieve a critical coupling using a readout speed limited by κᵣ, the following relationship between x and K may be defined: κᵣ=2χ.

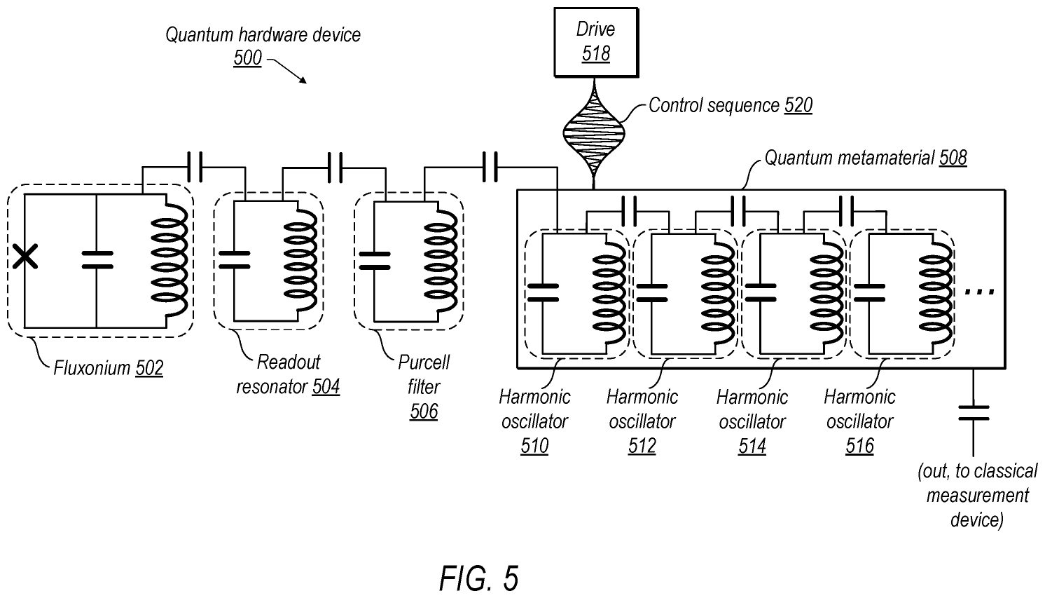

In some embodiments, illustrations depicted in FIGS. 4A and 4B that demonstrate an implementation of a control sequence that may be used to perform readout via dispersive coupling between fluxonium hardware components and a readout resonator may additionally be applied to performing readout via dispersive coupling between fluxonium 502 and readout resonator 504, shown in FIG. 5.

FIG. 5 illustrates another hardware layout of a quantum hardware device that is configured to perform readout of a fluxonium qubit by dispersively coupling hardware components that implement a fluxonium qubit to a readout resonator, which, in turn, is coupled to a Purcell filter, which, in turn, is coupled to a quantum metamaterial, according to some embodiments.

In some embodiments, quantum hardware device 500 may configured to perform readout of a fluxonium qubit, implemented using fluxonium 502, using dispersive readout techniques additionally described herein with regard to at least FIGS. 1-4B and 6. As shown in FIG. 5, fluxonium hardware components are configured in parallel, such as that which is depicted with regard to fluxonium 502, and may be coupled to readout resonator 504. Readout resonator 504 may then be coupled to Purcell filter 506, which may then be coupled to quantum metamaterial 508. A signal corresponding to a quantum state of a fluxonium qubit that is implemented using fluxonium 502 may be transmitted from fluxonium 502, through readout resonator 504, then through Purcell filter 506, and through harmonic oscillators 510, 512, 514, and 516 of quantum metamaterial 508, wherein the signal may then be read out using a classical measurement device.

As described above with regard to FIGS. 1-4B, control sequence 520 may be emitted using drive 518 such that readout resonator 504 is driven at its resonance frequency, causing information pertaining to a quantum state of the corresponding fluxonium qubit to be propagated through to a classical measurement device.

As additionally depicted in FIG. 5, Purcell filter 506 may be coupled to readout resonator 504 and to quantum metamaterial 508 in order to provide further protection of a fluxonium qubit, such as during performance of readout. In a first example using an architecture shown in FIG. 1, readout resonator 104 may be placed in between fluxonium 102 and quantum metamaterial 106 such that, when control sequence 118 is emitted, readout resonator 104 may act as a buffer between fluxonium 102 and quantum metamaterial 106, which in turn acts as a transmission line during such readout. Providing an isolation for the fluxonium qubit allows for readout to be performed in such a way that a quantum state of the qubit is not collapsed, which may also be referred to herein as QND measurements and/or any other methods of performing readout by indirectly extracting a quantum state from a fluxonium qubit. Evidence of protection provided by inserting readout resonator 104 in between fluxonium 102 and quantum metamaterial 106 is additionally described with regard to FIG. 4A herein. As shown in frequency domain 400, fluxonium qubit frequency is located outside of the passband of the quantum metamaterial, such that an energy state of the fluxonium qubit cannot decay through readout resonator 104 and into quantum metamaterial 106. In addition, since a resonance frequency of readout resonator 104 is in the passband of the quantum metamaterial, when readout resonator 104 is driven at its resonance frequency by an emission of control sequence 118, an excited energy state of readout resonator 104 then quickly decays into quantum metamaterial 106, allowing readout to be performed.

In another example using an architecture shown in FIG. 5, readout resonator 504 and Purcell filter 506 are placed in between fluxonium 502 and quantum metamaterial 508 in order to provide further isolation and protection of a quantum state of a fluxonium qubit. In some embodiments, Purcell filter 506 may be configured to provide a buffering against radiative, or “Purcell,” decay. Furthermore, Purcell filter 506 may also protect a fluxonium qubit from environmental noise, such as during performance of readout.

Moreover, as additionally described above with regard to FIG. 1, it should be understood that, in some embodiments, fluxonium 502 may be connected to one or more other sets of fluxonium hardware components of a larger-scale quantum hardware device that implement respective and additional fluxonium qubits. For example, fluxonium 502 may be implemented within quantum processing core 1420, as shown in FIG. 14, wherein readout resonator 504, Purcell filter 506, quantum metamaterial 508, and drive 518 may then be implemented within quantum readout devices 1440, as additionally shown in FIG. 14.

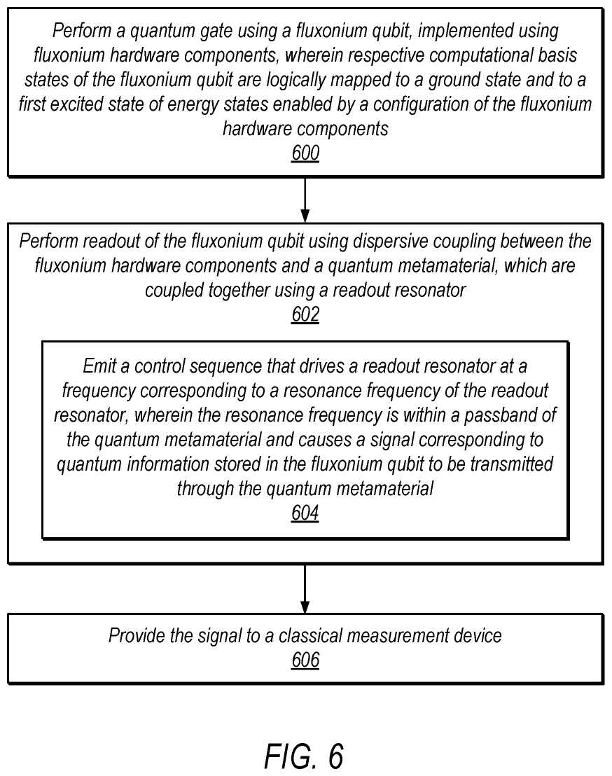

FIG. 6 illustrates a process of performing readout of a quantum superposition state of a fluxonium qubit using dispersive coupling, according to some embodiments.

In some embodiments, quantum hardware devices, such as quantum hardware devices 100 and 500, may be configured to induce dispersive coupling between fluxonium hardware components that implement a fluxonium qubit and a readout resonator, which is additionally coupled to a quantum metamaterial. Such a hardware configuration may then be used in order to read out a quantum state of the fluxonium qubit while said qubit remains protected from energy decay.

In block 600, a quantum gate is performed using a fluxonium qubit, wherein the quantum gate may resemble a configuration of one or more quantum gates 210 within an overall execution of quantum circuit 200, shown in FIG. 2. Then, following the performance of the quantum gate, readout may be performed in order to extract information about a quantum state of the fluxonium qubit following the logical quantum operation that was performed on the qubit during the gate, as shown in block 602.

In some embodiments, in order to perform the readout step, a control sequence having a frequency corresponding to a resonance frequency of the readout resonator is emitted, as shown in block 604. By emitting a control sequence that drives a readout resonator at a frequency corresponding to its resonance frequency, information pertaining to the quantum state of the fluxonium qubit is transmitted from the fluxonium hardware components, through the readout resonator, into the quantum metamaterial, wherein it is then read out by a classical measurement device, as shown in block 606.

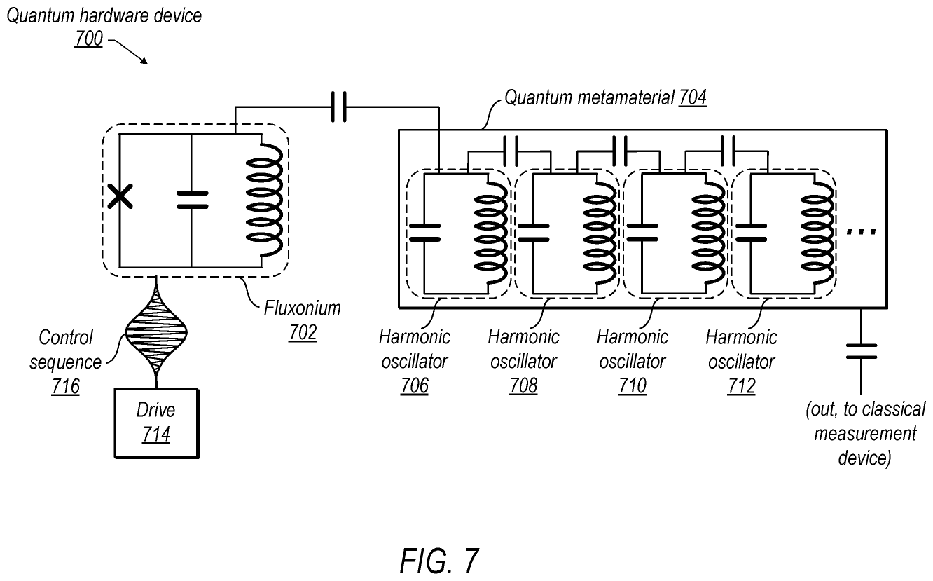

FIG. 7 illustrates a hardware layout of a quantum hardware device that is configured to perform both fluorescent readout of a fluxonium qubit and fluorescent reset of the fluxonium qubit by coupling hardware components that implement a fluxonium qubit to a quantum metamaterial, according to some embodiments.

In some embodiments, readout and reset steps, such as those depicted as readouts 212 and 214 and resets 206, 208, 216, and 218 in FIG. 2, may be performed using resonance fluorescence from a fluxonium qubit, implemented using fluxonium hardware components, to a quantum metamaterial.

In some embodiments, a given configuration of quantum hardware components, such as that which is shown in FIG. 7, may be used to enable resonance fluorescence from fluxonium 702 to quantum metamaterial 704. It may be understood that, due to a hardwiring of capacitive coupling between said respective components, the resonance fluorescence may be assumed to be “on-going” throughout the performance of various quantum gates, and throughout the performance of readout and reset, etc. (see also various steps within a performance for quantum circuit 200, as additionally described with regard to FIG. 2 herein).

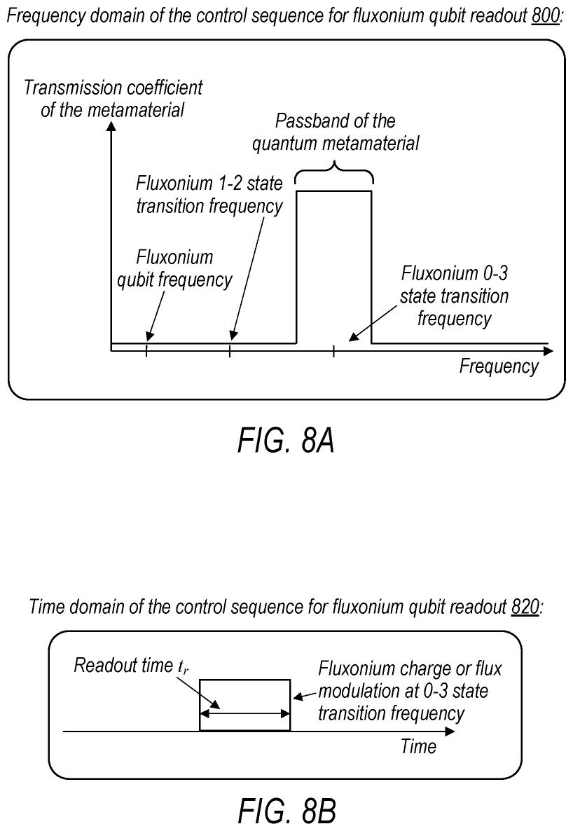

In some embodiments, in order to extract information about a quantum state of a fluxonium qubit at various intervals during a given quantum computation (see also description herein pertaining to an example quantum circuit 200 in FIG. 2), readout of a fluxonium qubit, implemented using fluxonium hardware components of fluxonium 702, may be performed by transmitting a signal, corresponding to the information about the quantum state, through quantum metamaterial 704, wherein the signal may then be read out by a classical measurement device. As additionally illustrated in FIGS. 8A and 8B herein, by emitting a control sequence, such as control sequence 716, that has a frequency corresponding to a fluxonium 0-3 state transition frequency (see also additional description pertaining to FIG. 3B herein), information about a quantum state of the corresponding fluxonium qubit may be transmitted through quantum metamaterial 704 without collapsing the superposition quantum state of the fluxonium qubit. As also illustrated in FIGS. 8A and 8B herein, circuit parameters of quantum hardware device 700 may be configured such that the frequency corresponding to the fluxonium 0-3 state transition frequency is within a passband of quantum metamaterial 704, allowing for a quantum state of the fluxonium qubit to be read out without affecting energy states that are being used to logically map the computational basis states of the qubit.

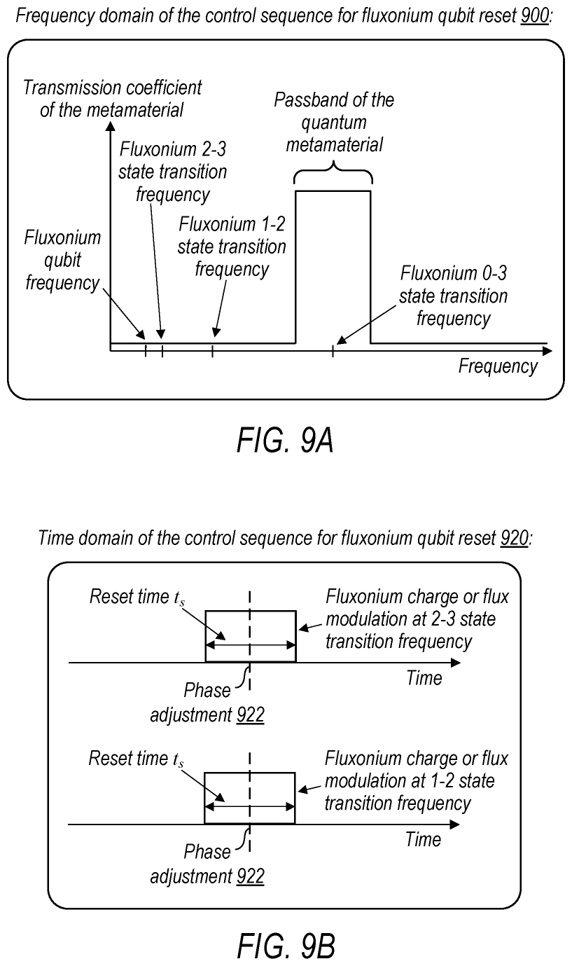

Moreover, by emitting another control sequence, which may also be incorporated in a discussion of control sequence 716 herein, such that one or more energy states of fluxonium energy state diagram 300 that are populated with a particle decay (e.g., fluoresce) back to the ground state, a fluxonium qubit may be reset in preparation for another round of quantum gates. Examples of control sequences pertaining to fluxonium qubit reset are additionally illustrated in FIGS. 9A-12B herein.

In some embodiments, quantum metamaterial 704 may act as a transmission line when coupled directly to fluxonium 702, such that the signal is rapidly propagated through respective harmonic oscillators of quantum metamaterial 704 and out towards a classical measurement device. As shown in FIG. 7, quantum metamaterial 704 includes at least harmonic oscillators 706, 708, 710, and 712. It may be understood that additional implementations of quantum metamaterial 704 may include fewer harmonic oscillators or more harmonic oscillators than a number depicted in FIG. 7, and that a number of harmonic oscillators included within quantum metamaterial 704 may determine, at least in part, a width of a passband of quantum metamaterial 704, in addition to various other circuit parameters of an overall hardware configuration of quantum hardware device 700. Moreover, fluxonium 702 is shown as being directly coupled to harmonic oscillator 706 in FIG. 7. However, in other embodiments, fluxonium 702 may instead be directly coupled to harmonic oscillator 706, 708, 710, or 712, etc.

In some embodiments, drive 714 may resemble a microwave pulse generator and/or other device that is configured to emit, or “shine,” a microwave pulse onto fluxonium 702, and either readout or reset may be performed, according to a given implementation of control sequence 716 that is being emitted. Drive 714 may be further configured to receive drive control instructions from a classical computing device, such as classical computing device 1500, wherein the drive control instructions may include information such as duration of the pulse to be emitted, frequency/frequencies of the pulse to be emitted, timing of when to emit the pulse within an execution of quantum circuit 200, etc.

Moreover, it should be understood that, while FIG. 7 depicts an implementation in which drive 714 is coupled to fluxonium 702 in order to perform readout and/or reset steps, additional implementations of quantum hardware device 700 (e.g., wherein drive 714 is coupled to quantum metamaterial 704) that may still be used to perform readout and reset steps using resonance fluorescence of a fluxonium qubit, implemented using fluxonium hardware components, into a quantum metamaterial are meant to be incorporated in the discussion herein. For example, in some embodiments in which a control sequence 716 is used to perform readout and is coupled to fluxonium 702, the control sequence 716 may be used to “pump” energy into a system defined by hardware components of quantum hardware device 700 such that the energy corresponds to a fluxonium 0-3 state transition frequency, and a signal that is conditional upon a given quantum state of the corresponding fluxonium qubit is transmitted through quantum metamaterial 704 and towards a classical measurement device. In another example, in some embodiments in which a control sequence 716 is used to perform readout and is coupled to quantum metamaterial 704, the control sequence 716 may be used to “pump” energy into a system defined by hardware components of quantum hardware device 700 such that a comparison of energy that is input to the system using control sequence 716 with respect an energy of a signal read out by a classical measurement device provides information pertaining to a given quantum state of the corresponding fluxonium qubit.

In some embodiments, in order to configure resonance fluorescence from a fluxonium qubit implemented using fluxonium 702 into quantum metamaterial 704 using capacitive coupling, fluxonium 702 may be capacitively coupled to quantum metamaterial 704, as shown in FIG. 7. However, in some embodiments, inductive coupling may be used in order to configure such resonance fluorescence.

Furthermore, as additionally described above with regard to FIGS. 1 and 5, it should be understood that, in some embodiments, fluxonium 702 may be connected to one or more other sets of fluxonium hardware components of a larger-scale quantum hardware device that implement respective and additional fluxonium qubits. For example, fluxonium 702 may be implemented within quantum processing core 1420, as shown in FIG. 14, wherein quantum metamaterial 704 and drive 714 may then be implemented within quantum readout devices 1440, as additionally shown in FIG. 14. Moreover, it should be understood that a grounding of one or more of the hardware components of quantum hardware device 700 may also be required, and is meant to be encompassed within discussion of a given larger architecture design implementation that includes quantum hardware device 700, such as that which is described with regard to implementation of a quantum computer 1430.

FIGS. 8A and 8B illustrate a control sequence, in the frequency and time domains, respectively, for performing readout of a fluxonium qubit using a hardware layout such as that which is shown in FIG. 7, according to some embodiments.

In some embodiments, a control sequence, such as control sequence 716, which is configured to be emitted by drive 714 and cause a non-destructive measurement of a quantum state to be transmitted from corresponding fluxonium hardware components (e.g., fluxonium 702), and into quantum metamaterial 704 for read out, may resemble depictions in frequency domain 800 and time domain 820.

As shown in frequency domain 800, circuit parameters of quantum hardware device 700 are configured such that a passband of quantum metamaterial 704 includes a range of frequencies that is higher than both the fluxonium qubit frequency and the fluxonium 1-2 state transition frequency (see also description pertaining to fluxonium energy state transition frequencies 320 herein). Furthermore, circuit parameters of quantum hardware device 700 are additionally configured such that the fluxonium 0-3 state transition frequency is within a range of frequencies that define the passband of quantum metamaterial 704. As such, when control sequence 716 is emitted, population within the ground state is excited to the third excited state (see also description pertaining to fluxonium energy state diagram 300), and then decays to the ground state, and information pertaining to a quantum state of the fluxonium qubit implemented using fluxonium 702 is then transmitted through quantum metamaterial 704 towards a classical measurement device.

Furthermore, as the fluxonium qubit frequency is configured to reside outside of the passband of the quantum metamaterial, energy held within the energy states corresponding to the computational basis states of the fluxonium qubit cannot decay into the quantum metamaterial, providing protection of the quantum state of the fluxonium qubit, even during performance of readout. In some embodiments, the fluxonium 1-2 state transition frequency may be configured to also reside outside of the passband of the quantum metamaterial, as this particular transition frequency may be used during performance of some quantum gates, and therefore should also remain isolated from the passband such that energy at this frequency does not decay into the quantum metamaterial.

As further depicted with regard to time domain 820, control sequence 716 may have a duration of time defined by readout time tᵣ. In some embodiments, readout time tᵣ may be used to define an amount of time during which a charge modulation and/or flux modulation of the fluxonium qubit is occurring at a driving frequency corresponding to the fluxonium 0-3 state transition frequency resonance frequency.

It may be understood that a depiction of a control sequence, such as control sequence 716 in FIG. 7, may refer either to a control sequence configured to enable readout of a fluxonium qubit or a control sequence configured to enable reset of a fluxonium qubit, depending upon a given moment in time during an overall execution of a quantum circuit, such as quantum circuit 200.

FIGS. 9A and 9B illustrate a first control sequence, in the frequency and time domains, respectively, for performing reset of a fluxonium qubit using a hardware layout such as that which is shown in FIG. 7, according to some embodiments.

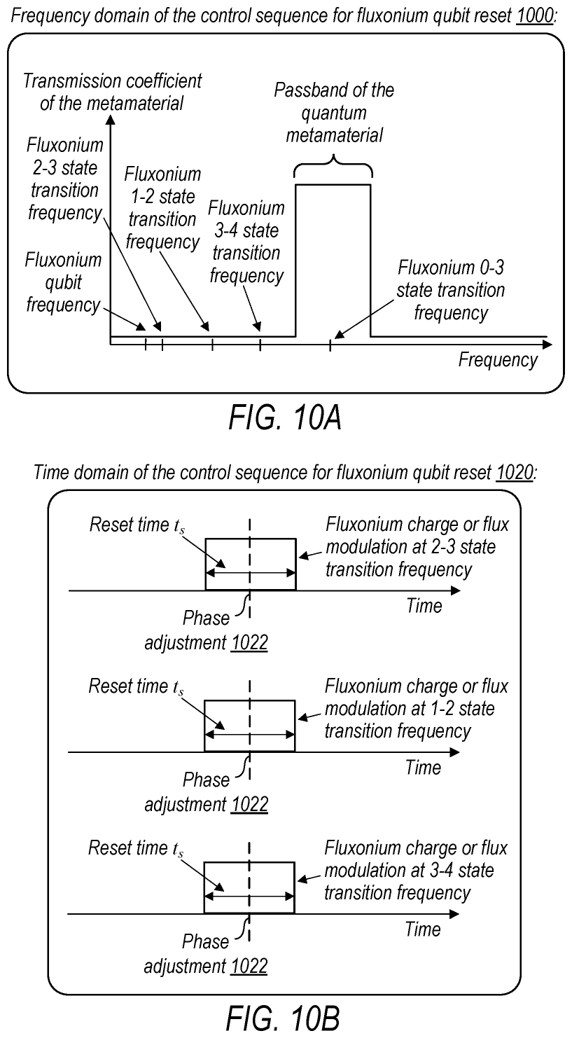

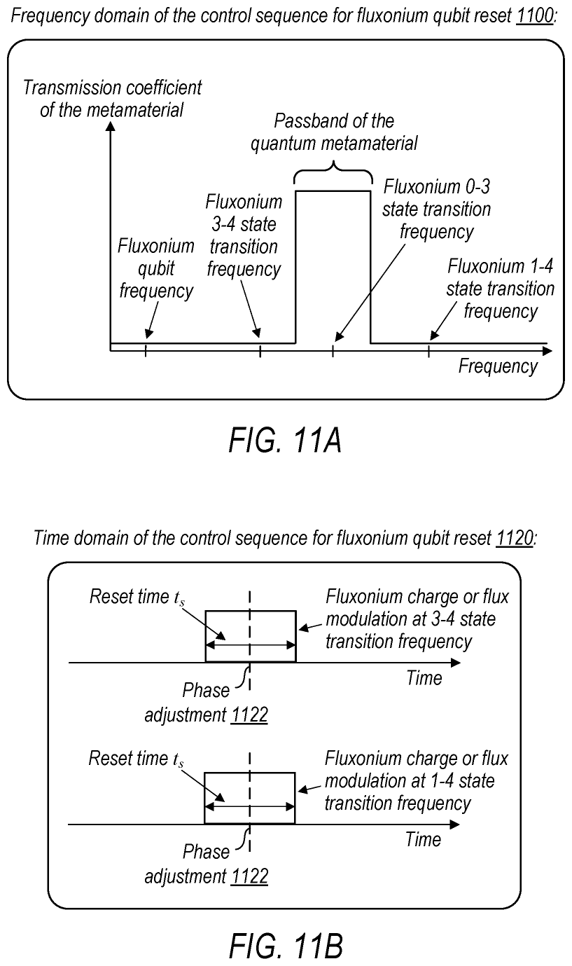

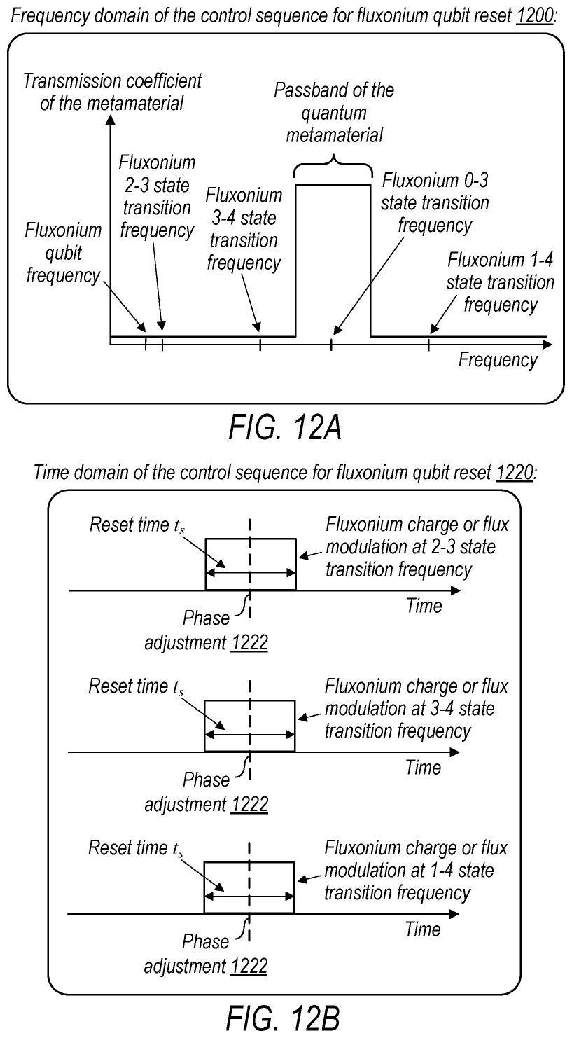

In some embodiments for methods of performing reset of fluxonium qubits, such as those depicted in FIGS. 9A-12B, frequencies that are used within a control sequence 716 for reset may refer to continuous waveform (CW) pulses, single qubit pulses, Tt pulses, and/or some combination of such pulses in order to induce fluorescent-based reset of the fluxonium qubit. In addition, it may be understood that FIGS. 9A-12B may resemble at least four implementations of control sequences that may be used to reset fluxonium qubits. For example, in some embodiments, a control sequence such as that which is depicted in FIGS. 9A and 9B may be provided as drive control instructions to drive 714 in order to perform resets 206 and 208 within the overall execution of quantum circuit 200, while a control sequence such as that which is depicted in FIGS. 10A and 10B may alternatively be provided as drive control instructions to drive 714 in order to perform resets 216 and 218, and so on. Furthermore, in some embodiments, a control sequence such as that which is depicted in FIGS. 11A and 11B may be provided as drive control instructions to drive 714 in order to perform reset 206, while a control sequence such as that which is depicted in FIGS. 12A and 12B may be provided as drive control instructions to drive 714 in order to sequentially perform reset 208, and so on.

In some embodiments, a control sequence, such as control sequence 716, which is configured to be emitted by drive 714 and cause reinitialization of a quantum state of the corresponding fluxonium qubit into a ground state of the fluxonium, may resemble depictions in frequency domain 900 and time domain 920.

As shown in frequency domain 900, circuit parameters of quantum hardware device 700 are configured such that a passband of quantum metamaterial 704 includes a range of frequencies that is higher than both the fluxonium qubit frequency and the fluxonium 2-3 and 1-2 state transition frequencies (see also description pertaining to fluxonium energy state transition frequencies 320 herein). Furthermore, circuit parameters of quantum hardware device 700 are additionally configured such that the fluxonium 0-3 state transition frequency is within a range of frequencies that define the passband of quantum metamaterial 704. As such, when control sequence 716 is emitted, population in either or both of the first and second excited energy states are excited to the third excited energy state (see also description pertaining to fluxonium energy state diagram 300), which then decays to the ground state, and which is then transmitted through quantum metamaterial 704 since the fluxonium 0-3 state transition frequency is within the passband of the quantum metamaterial.

As further depicted with regard to time domain 920, control sequence 716 may have a duration of time defined by reset time tₛ. In some embodiments, reset time tₛ may be used to define an amount of time during which a charge modulation and/or flux modulation of the fluxonium qubit is occurring at frequencies corresponding to both the fluxonium 2-3 state transition frequency and the fluxonium 1-2 state transition frequency. In some embodiments, such a control sequence that emits multiple frequencies simultaneously for a duration defined by reset time tₛ may be further defined as a control sequence that performs reset by “pumping” one or more populated energy states (e.g., the first and/or second excited energy states) into a transition frequency that is within the passband of the quantum metamaterial (e.g., the fluxonium 0-3 state transition frequency).

FIGS. 10A and 10B illustrate a second control sequence, in the frequency and time domains, respectively, for performing reset of a fluxonium qubit using a hardware layout such as that which is shown in FIG. 7, according to some embodiments.

In some embodiments, a control sequence, such as control sequence 716, which is configured to be emitted by drive 714 and cause reset of a quantum state of the corresponding fluxonium qubit into a ground state of the fluxonium, may resemble depictions in frequency domain 1000 and time domain 1020.

As shown in frequency domain 1000, circuit parameters of quantum hardware device 700 are configured such that a passband of quantum metamaterial 704 includes a range of frequencies that is higher than the fluxonium qubit frequency and is higher than the fluxonium 2-3, 1-2, and 3-4 state transition frequencies (see also description pertaining to fluxonium energy state transition frequencies 320 herein). Furthermore, circuit parameters of quantum hardware device 700 are additionally configured such that the fluxonium 0-3 state transition frequency is within a range of frequencies that define the passband of quantum metamaterial 704. As such, when control sequence 716 is emitted, population in any combination of the first, second, and fourth excited energy states are excited (or decayed with regard to the fourth excited energy state) to the third excited energy state (see also description pertaining to fluxonium energy state diagram 300), which then decays to the ground state, and which is then transmitted through quantum metamaterial 704 since the fluxonium 0-3 state transition frequency is within the passband of the quantum metamaterial.

As further depicted with regard to time domain 1020, control sequence 716 may have a duration of time defined by reset time tₛ. In some embodiments, reset time tₛ may be used to define an amount of time during which a charge modulation and/or flux modulation of the fluxonium qubit is occurring at frequencies corresponding to the fluxonium 2-3 state transition frequency, the fluxonium 1-2 state transition frequency, and the fluxonium 3-4 state transition frequency. In some embodiments, such a control sequence that emits multiple frequencies simultaneously for a duration defined by reset time tₛ may be further defined as a control sequence that performs reset by “pumping” one or more populated energy states (e.g., the first, second, and/or fourth excited energy states) into a transition frequency that is within the passband of the quantum metamaterial (e.g., the fluxonium 0-3 state transition frequency).

FIGS. 11A and 11B illustrate a third control sequence, in the frequency and time domains, respectively, for performing reset of a fluxonium qubit using a hardware layout such as that which is shown in FIG. 7, according to some embodiments.

In some embodiments, a control sequence, such as control sequence 716, which is configured to be emitted by drive 714 and cause reset of a quantum state of the corresponding fluxonium qubit into a ground state of the fluxonium, may resemble depictions in frequency domain 1100 and time domain 1120.

As shown in frequency domain 1100, circuit parameters of quantum hardware device 700 are configured such that a passband of quantum metamaterial 704 includes a range of frequencies that is higher than both the fluxonium qubit frequency and 3-4 state transition frequency (see also description pertaining to fluxonium energy state transition frequencies 320 herein). In addition, circuit parameters of quantum hardware device 700 are configured such that the passband of quantum metamaterial 704 includes a range of frequencies that is also lower than the fluxonium 1-4 state transition frequency.

Furthermore, circuit parameters of quantum hardware device 700 are additionally configured such that the fluxonium 0-3 state transition frequency is within a range of frequencies that define the passband of quantum metamaterial 704. As such, when control sequence 716 is emitted, population in any combination of the first, second, and fourth excited energy states are excited (or decayed with regard to the fourth excited energy state) to the third excited energy state (see also description pertaining to fluxonium energy state diagram 300), which then decays to the ground state, and which is then transmitted through quantum metamaterial 704 since the fluxonium 0-3 state transition frequency is within the passband of the quantum metamaterial.

As further depicted with regard to time domain 1120, control sequence 716 may have a duration of time defined by reset time tₛ. In some embodiments, reset time tₛ may be used to define an amount of time during which a charge modulation and/or flux modulation of the fluxonium qubit is occurring at frequencies corresponding to the fluxonium 3-4 state transition frequency and the fluxonium 1-4 state transition frequency. In some embodiments, such a control sequence that emits multiple frequencies simultaneously for a duration defined by reset time tₛ may be further defined as a control sequence that performs reset by “pumping” one or more populated energy states (e.g., the first, second, and/or fourth excited energy states) into a transition frequency that is within the passband of the quantum metamaterial (e.g., the fluxonium 0-3 state transition frequency).

FIGS. 12A and 12B illustrate a fourth control sequence, in the frequency and time domains, respectively, for performing reset of a fluxonium qubit using a hardware layout such as that which is shown in FIG. 7, according to some embodiments.

In some embodiments, a control sequence, such as control sequence 716, which is configured to be emitted by drive 714 and cause reset of a quantum state of the corresponding fluxonium qubit into a ground state of the fluxonium, may resemble depictions in frequency domain 1200 and time domain 1220.

As shown in frequency domain 1200, circuit parameters of quantum hardware device 700 are configured such that a passband of quantum metamaterial 704 includes a range of frequencies that is higher than the fluxonium qubit frequency and is higher than the fluxonium 2-3, 1-2, and 3-4 state transition frequencies (see also description pertaining to fluxonium energy state transition frequencies 320 herein). In addition, circuit parameters of quantum hardware device 700 are configured such that the passband of quantum metamaterial 704 includes a range of frequencies that is also lower than the fluxonium 1-4 state transition frequency.

Furthermore, circuit parameters of quantum hardware device 700 are additionally configured such that the fluxonium 0-3 state transition frequency is within a range of frequencies that define the passband of quantum metamaterial 704. As such, when control sequence 716 is emitted, population in any combination of the first, second, and fourth excited energy states are excited (or decayed with regard to the fourth excited energy state) to the third excited energy state (see also description pertaining to fluxonium energy state diagram 300), which then decays to the ground state, and which is then transmitted through quantum metamaterial 704 since the fluxonium 0-3 state transition frequency is within the passband of the quantum metamaterial.

As further depicted with regard to time domain 1220, control sequence 716 may have a duration of time defined by reset time tₛ. In some embodiments, reset time tₛ may be used to define an amount of time during which a charge modulation and/or flux modulation of the fluxonium qubit is occurring at frequencies corresponding to the fluxonium 2-3 state transition frequency, the fluxonium 3-4 state transition frequency, and the fluxonium 1-4 state transition frequency. In some embodiments, such a control sequence that emits multiple frequencies simultaneously for a duration defined by reset time tₛ may be further defined as a control sequence that performs reset by “pumping” one or more populated energy states (e.g., the first, second, and/or fourth excited energy states) into a transition frequency that is within the passband of the quantum metamaterial (e.g., the fluxonium 0-3 state transition frequency).

In some embodiments, drive control instructions that are provided to drive 714 and that enable any of the control sequences for reset of a fluxonium qubit depicted in FIGS. 9A-12B herein may additionally include instructions for phase adjustment in order to suppress a potential for dark state trapping. As such control sequences for fluxonium qubit reset simultaneously emit pulses at multiple frequencies, there may be an increased probability that any of the first, second, third, or fourth excited energy states may become insensitive to the “pumping” of the populated energy states into a transition frequency that is within the passband of the quantum metamaterial, causing population within one of the excited energy states to remain in said excited energy state rather than decay into the quantum metamaterial. As such, drive control instructions for performing fluxonium qubit reset by methods described herein with regard to resonance fluorescence may include a phase adjustment to pulses emitted during control sequence 716 for reset. By including a shift to the phase of the respective pulses that are simultaneously being emitted, a potential for dark state trapping is suppressed. Examples of such phase adjustments are shown in FIGS. 9B, 10B, 11B, and 12B with regard to phase adjustments 922, 1022, 1122, and 1222, respectively, wherein the vertical dashed lines denote respective moments in time at which point a phase adjustment occurs. As shown in the figures, the respective phase adjustments may occur at a moment in time that is both after the start of control sequence 716 and before the end of control sequence 716.

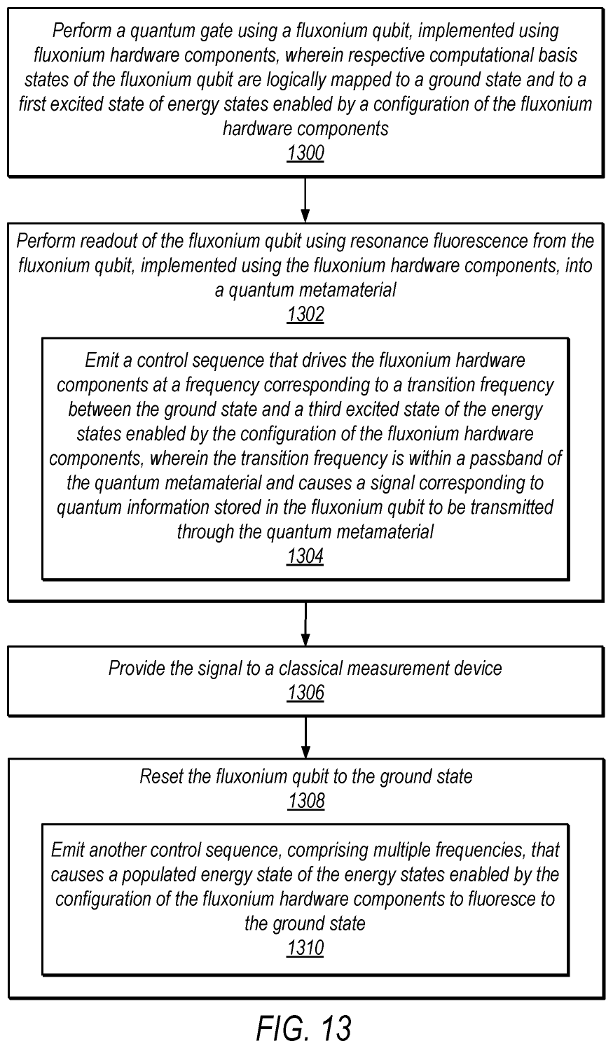

FIG. 13 illustrates a process of performing fluorescent readout and reset of a fluxonium qubit, according to some embodiments.

In some embodiments, hardware layouts of quantum hardware devices, such as a hardware layout of quantum hardware device 700, may be configured to cause resonance fluorescence to occur from a fluxonium qubit, implemented using fluxonium hardware components, to a quantum metamaterial. Such a hardware configuration may then be used in order to read out a quantum state of the fluxonium qubit while said qubit remains protected from energy decay, and in order to reset the fluxonium qubit.

In block 1300, a quantum gate is performed using a fluxonium qubit, wherein the quantum gate may resemble a configuration of one or more quantum gates 210 within an overall execution of quantum circuit 200, shown in FIG. 2. Then, following the performance of the quantum gate, readout may be performed in order to extract information about a quantum state of the fluxonium qubit following the logical quantum operation that was performed on the qubit during the gate, as shown in block 1302.

In some embodiments, in order to perform the readout, a control sequence having a frequency corresponding to a fluxonium 0-3 state transition frequency is emitted, as shown in block 1304. By emitting a control sequence that drives the system at a frequency corresponding to a fluxonium 0-3 state transition frequency, information pertaining to the quantum state of the fluxonium qubit to be transmitted from the fluxonium hardware components into the quantum metamaterial, wherein it is then read out by a classical measurement device, as shown in block 1306.

Following completion of readout, resonance fluorescence may additionally be used to induce reinitialization of a fluxonium qubit to a ground state, as shown in blocks 1308 and 1310. Another control sequence may be emitted that causes one or more populated energy states to be excited, or decayed, into the third excited energy state, wherein the energy then decays (or fluoresces) to the ground state and into the quantum metamaterial, according to some embodiments. Such a control sequence for reset may be applied to resets 206, 208, 216, and 218 within an overall execution of quantum circuit 200.

FIG. 14 is a block diagram illustrating an example quantum hardware device that may be configured to execute quantum gates between fluxonium qubits, and to perform readout and reset steps in between execution of said quantum gates, according to some embodiments.

As shown in FIG. 14, a quantum hardware device 1400 may comprise one or more central quantum processing units (QPUs) and/or quantum processing cores 1420 that, collectively, implement a quantum computer 1430. Various configurations of physical qubits may be included in implementation of quantum computer 1430 wherein a given subset of a total number of qubits may represent quantum processing core 1420 and another given subset of qubits may be used to implement magic state factories, additional routing space, and/or additional quantum processing cores that are accessible via lattice surgery, as shown in block 1410. Portions of quantum computations and/or operations may be performed in quantum processing core 1430, wherein computationally intensive logical computations may use magic state factories within block 1410. in order to produce magic states that may be used to store intermediate computations such that they are held in memory during such quantum computations. In some embodiments, a given magic state factory of block 1410 may be merged with quantum processing core 1420 during a procedure such as lattice surgery in order for information to pass between such components of the quantum computer.

As related to the description herein, one or more fluxonium qubits within implementation of quantum computer 1430 may additionally be coupled to a quantum readout device for measurements of quantum states following performance of one or more quantum gates such as two-qubit entangling gates described herein. The given quantum readout device may be locally connected to various qubits of quantum processing core 1420, as shown by interaction arrows to/from block 1440.

Depending upon factors such as type(s) of qubit technologies used (e.g., superconducting architectures), type(s) of gates performed between said qubits (e.g., entangling gates, QND measurements), etc., quantum hardware device 1410 may also comprise various control devices (e.g., microwave pulse generators, lasers, devices for temperature, magnetic, and/or other environmental controls pertaining to local environments of the grid of qubits within implementation of quantum computer 1430, etc.) that may be used to maintain and/or transform various properties of the qubits and/or other physical components of a given quantum computer, as shown via local environmental control devices within block 1440. For example, a drive such as drive 116, drive 518, drive 714, etc. may be locally coupled to one or more quantum hardware components within quantum processing core 1420, such that various control sequences emitted from drive 116, drive 518, or drive 714 may be used to perform readout and/or reinitialize various qubits of quantum processing core 1420 into their respective ground states.

In some embodiments in which local environmental control devices 1440 include a processor such as processors 1510, local environmental control devices 1440 may additionally be configured to interact with other devices 1460 via network 1450. In some embodiments, other devices 1460 may include classical computing devices such as classical computing device 1500, which may be configured to interact with quantum hardware device 1400 either locally or remotely.

### Illustrative Computer System

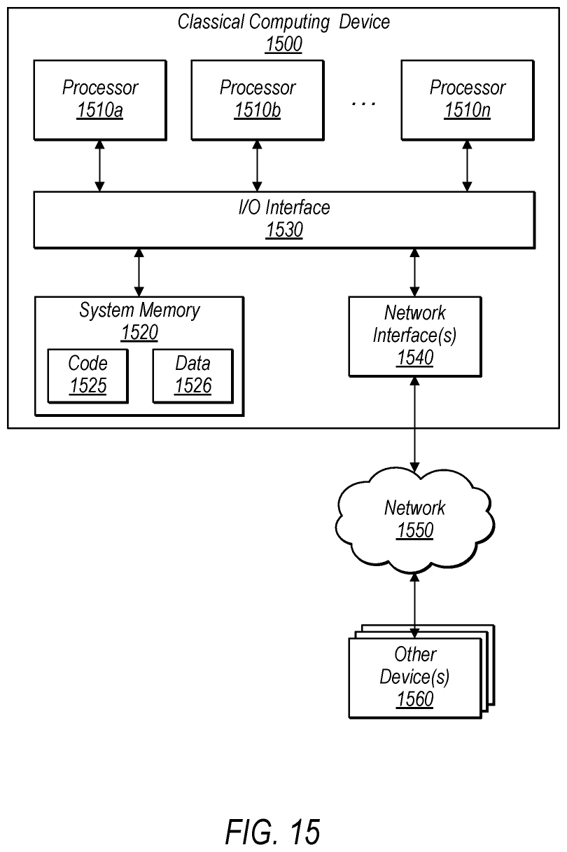

FIG. 15 is a block diagram illustrating an example classical computing device that may be used in at least some embodiments.

FIG. 15 illustrates such a general-purpose classical computing device 1500 as may be used in any of the embodiments described herein. In the illustrated embodiment, classical computing device 1500 includes one or more processors 1510 coupled to a system memory 1520 (which may comprise both non-volatile and volatile memory modules) via an input/output (I/O) interface 1530. Classical computing device 1500 further includes a network interface 1540 coupled to I/O interface 1530.

In various embodiments, classical computing device 1500 may be a uniprocessor system including one processor 1510, or a multiprocessor system including several processors 1510 (e.g., two, four, eight, or another suitable number). Processors 1510 may be any suitable processors capable of executing instructions. For example, in various embodiments, processors 1510 may be general-purpose or embedded processors implementing any of a variety of instruction set architectures (ISAs), such as the ×86, PowerPC, SPARC, or MIPS ISAs, or any other suitable ISA. In multiprocessor systems, each of processors 1510 may commonly, but not necessarily, implement the same ISA. In some implementations, graphics processing units (GPUs) may be used instead of, or in addition to, conventional processors.

System memory 1520 may be configured to store instructions and data accessible by processor(s) 1510. In at least some embodiments, the system memory 1520 may comprise both volatile and non-volatile portions; in other embodiments, only volatile memory may be used. In various embodiments, the volatile portion of system memory 1520 may be implemented using any suitable memory technology, such as static random-access memory (SRAM), synchronous dynamic RAM or any other type of memory. For the non-volatile portion of system memory (which may comprise one or more NVDIMMs, for example), in some embodiments flash-based memory devices, including NAND-flash devices, may be used. In at least some embodiments, the non-volatile portion of the system memory may include a power source, such as a supercapacitor or other power storage device (e.g., a battery). In various embodiments, memristor based resistive random access memory (ReRAM), three-dimensional NAND technologies, Ferroelectric RAM, magnetoresistive RAM (MRAM), or any of various types of phase change memory (PCM) may be used at least for the non-volatile portion of system memory. In the illustrated embodiment, program instructions and data implementing one or more desired functions, such as those methods, techniques, and data described above, are shown stored within system memory 1520 as code 1525 and data 1526.

In some embodiments, I/O interface 1530 may be configured to coordinate I/O traffic between processor 1510, system memory 1520, and any peripheral devices in the device, including network interface 1540 or other peripheral interfaces such as various types of persistent and/or volatile storage devices. In some embodiments, I/O interface 1530 may perform any necessary protocol, timing or other data transformations to convert data signals from one component (e.g., system memory 1520) into a format suitable for use by another component (e.g., processor 1510). In some embodiments, I/O interface 1530 may include support for devices attached through various types of peripheral buses, such as a variant of the Peripheral Component Interconnect (PCI) bus standard or the Universal Serial Bus (USB) standard, for example. In some embodiments, the function of I/O interface 1530 may be split into two or more separate components, such as a north bridge and a south bridge, for example. Also, in some embodiments some or all of the functionality of I/O interface 1530, such as an interface to system memory 1520, may be incorporated directly into processor 1510.

Network interface 1540 may be configured to allow data to be exchanged between classical computing device 1500 and other devices 1560 attached to a network or networks 1550, such as other computer systems or devices as illustrated in FIG. 1 through FIG. 14, for example. In various embodiments, network interface 1540 may support communication via any suitable wired or wireless general data networks, such as types of Ethernet network, for example. Additionally, network interface 1540 may support communication via telecommunications/telephony networks such as analog voice networks or digital fiber communications networks, via storage area networks such as Fibre Channel SANs, or via any other suitable type of network and/or protocol.

In some embodiments, system memory 1520 may represent one embodiment of a computer-accessible medium configured to store at least a subset of program instructions and data used for implementing the methods and apparatus discussed in the context of FIG. 1 through FIG. 14. However, in other embodiments, program instructions and/or data may be received, sent or stored upon different types of computer-accessible media. Generally speaking, a computer-accessible medium may include non-transitory storage media or memory media such as magnetic or optical media, e.g., disk or DVD/CD coupled to classical computing device 1500 via I/O interface 1530. A non-transitory computer-accessible storage medium may also include any volatile or non-volatile media such as RAM (e.g., SDRAM, DDR SDRAM, RDRAM, SRAM, etc.), ROM, etc., that may be included in some embodiments of classical computing device 1500 as system memory 1520 or another type of memory. In some embodiments, a plurality of non-transitory computer-readable storage media may collectively store program instructions that when executed on or across one or more processors implement at least a subset of the methods and techniques described above. A computer-accessible medium may further include transmission media or signals such as electrical, electromagnetic, or digital signals, conveyed via a communication medium such as a network and/or a wireless link, such as may be implemented via network interface 1540. Portions or all of multiple classical computing devices such as that illustrated in FIG. 15 may be used to implement the described functionality in various embodiments; for example, software components running on a variety of different devices and servers may collaborate to provide the functionality. In some embodiments, portions of the described functionality may be implemented using storage devices, network devices, or special-purpose computer systems, in addition to or instead of being implemented using general-purpose computer systems. The term “classical computing device”, as used herein, refers to at least all these types of devices, and is not limited to these types of devices.

### CONCLUSION

Various embodiments may further include receiving, sending or storing instructions and/or data implemented in accordance with the foregoing description upon a computer-accessible medium. Generally speaking, a computer-accessible medium may include storage media or memory media such as magnetic or optical media, e.g., disk or DVD/CD-ROM, volatile or non-volatile media such as RAM (e.g. SDRAM, DDR, RDRAM, SRAM, etc.), ROM, etc., as well as transmission media or signals such as electrical, electromagnetic, or digital signals, conveyed via a communication medium such as network and/or a wireless link.

The various methods as illustrated in the Figures and described herein represent exemplary embodiments of methods. The methods may be implemented in software, hardware, or a combination thereof. The order of method may be changed, and various elements may be added, reordered, combined, omitted, modified, etc.

Various modifications and changes may be made as would be obvious to a person skilled in the art having the benefit of this disclosure. It is intended to embrace all such modifications and changes and, accordingly, the above description to be regarded in an illustrative rather than a restrictive sense.

What is claimed is:

1. A system, comprising:
fluxonium hardware components configured to implement a fluxonium qubit; and
a quantum readout device configured to perform readout of the fluxonium qubit, wherein the quantum readout device comprises:
a readout resonator, configured to dispersively couple to the fluxonium hardware components and to a quantum metamaterial;
the quantum metamaterial, coupled to a drive and to a classical measurement device, and configured to act as a bandpass filter; and
the drive,
wherein, to perform the readout of the fluxonium qubit, the quantum readout device is configured to emit, by the drive, a control sequence having a resonance frequency of the readout resonator, wherein:
the emission of the control sequence causes a signal, corresponding to quantum information stored in the fluxonium qubit, to be transmitted through the quantum metamaterial to the classical measurement device; and
a rate of transmission of the signal is based, at least in part, on a strength of the dispersive coupling between the readout resonator and the fluxonium hardware components.

2. The system of claim 1, wherein:
the quantum metamaterial comprises a plurality of harmonic oscillators, coupled in series with one another; and
a passband of the quantum metamaterial comprises resonant frequencies of the plurality of harmonic oscillators.

3. The system of claim 2, further comprising:
one or more classical computing devices configured to:
logically map respective computational basis states of the fluxonium qubit to a ground state and to a first excited state of energy states enabled by a configuration of the fluxonium hardware components;
determine the resonance frequency of the readout resonator to be used in the emission of the control sequence such that:
the resonance frequency is greater than a frequency corresponding to a transition frequency between the first excited state and a second excited state of the energy states enabled by the configuration of the fluxonium hardware components; and
the resonance frequency is within the passband of the quantum metamaterial; and
provide drive control instructions to the drive to be used for emission of the control sequence, wherein the drive control instructions comprise an indication of the determined resonance frequency to be used.

4. The system of claim 1, wherein:
the quantum readout device further comprises a Purcell filter, respectively coupled to the readout resonator and to the quantum metamaterial; and
the Purcell filter is configured to suppress a rate of Purcell decay.

5. The system of claim 1, wherein:
the fluxonium hardware components are capacitively coupled to the readout resonator; and
the readout resonator is capacitively coupled to the quantum metamaterial, such that dispersive coupling is enabled.

6. The system of claim 1, wherein:
the fluxonium hardware components are inductively coupled to the readout resonator; and
the readout resonator is inductively coupled to the quantum metamaterial, such that dispersive coupling is enabled.

7. A system, comprising:
fluxonium hardware components configured to implement a fluxonium qubit; and
a quantum hardware device configured to perform readout of the fluxonium qubit, wherein the quantum hardware device comprises:
a drive; and
a quantum metamaterial, configured to:
be coupled to the fluxonium hardware components; and
act as a bandpass filter,
wherein, to perform the readout of the fluxonium qubit, the quantum hardware device is configured to emit, by the drive, a control sequence having a frequency corresponding to a transition frequency between a ground state and a third excited state of energy states enabled by a configuration of the fluxonium hardware components, wherein:
the emission of the control sequence causes a signal, corresponding to quantum information stored in the fluxonium qubit, to be transmitted through the quantum metamaterial to a classical measurement device using resonance fluorescence; and
a rate of transmission of the signal is based, at least in part, on a strength of the resonance fluorescence between the fluxonium qubit, implemented using the fluxonium hardware components, and the quantum metamaterial.

8. The system of claim 7, wherein:
the quantum metamaterial comprises a plurality of harmonic oscillators, coupled in series with one another; and
a passband of the quantum metamaterial comprises resonant frequencies of the plurality of harmonic oscillators.

9. The system of claim 8, further comprising:
one or more classical computing devices configured to:
logically map respective computational basis states of the fluxonium qubit to the ground state and to a first excited state of the energy states enabled by the configuration of the fluxonium hardware components;
determine the frequency to be used in the emission of the control sequence such that the transition frequency between the ground state and the third excited state of the energy states enabled by the configuration of the fluxonium hardware components is within the passband of the quantum metamaterial; and
provide drive control instructions to the drive to be used for emission of the control sequence, wherein the drive control instructions comprise an indication of the determined resonance frequency to be used.

10. The system of claim 7, wherein:
the quantum hardware device is further configured to reset the fluxonium qubit into the ground state; and
to reset the fluxonium qubit, the quantum hardware device is configured to emit, by the drive, another control sequence comprising multiple frequencies, wherein one or more of the multiple frequencies causes a populated energy state of the energy states enabled by the configuration of the fluxonium hardware components to fluoresce to the ground state.

11. The system of claim 10, further comprising:
one or more classical computing devices configured to:
logically map respective computational basis states of the fluxonium qubit to the ground state and to a first excited state of the energy states enabled by the configuration of the fluxonium hardware components; and
provide drive control instructions to the drive to be used for emission of the other control sequence, wherein the drive control instructions comprise an indication of the multiple frequencies to be used.

12. The system of claim 10, wherein the multiple frequencies of the other control sequence comprise:
a first frequency corresponding to a transition frequency between a first excited state and a second excited state of energy states enabled by the configuration of the fluxonium hardware components; and
a second frequency corresponding to a transition frequency between the second excited state and the third excited state of energy states enabled by the configuration of the fluxonium hardware components.

13. The system of claim 10, wherein the multiple frequencies of the other control sequence comprise:
a first frequency corresponding to a transition frequency between a first excited state and a second excited state of the energy states enabled by the configuration of the fluxonium hardware components;
a second frequency corresponding to a transition frequency between the second excited state and the third excited state of the energy states enabled by the configuration of the fluxonium hardware components; and
a third frequency corresponding to a transition frequency between the third excited state and a fourth excited state of the energy states enabled by the configuration of the fluxonium hardware components.

14. The system of claim 10, wherein the multiple frequencies of the other control sequence comprise:
a first frequency corresponding to a transition frequency between the third excited state and a fourth excited state of the energy states enabled by the configuration of the fluxonium hardware components; and
a second frequency corresponding to a transition frequency between a first excited state and the fourth excited state of the energy states enabled by the configuration of the fluxonium hardware components.

15. The system of claim 10, wherein the multiple frequencies of the other control sequence comprise:
a first frequency corresponding to a transition frequency between the third excited state and a fourth excited state of the energy states enabled by the configuration of the fluxonium hardware components;
a second frequency corresponding to a transition frequency between a second excited state and the third excited state of the energy states enabled by the configuration of the fluxonium hardware components; and
a third frequency corresponding to a transition frequency between a first excited state and the fourth excited state of the energy states enabled by the configuration of the fluxonium hardware components.

16. The method of claim 10, wherein the other control sequence further comprises an adjustment in phase of the multiple frequencies at a moment in time during the emission of the other control sequence, wherein the adjustment in phase causes dark state trapping to be suppressed.

17. A method, comprising:
performing a quantum gate using a fluxonium qubit, implemented using fluxonium hardware components, wherein respective computational basis states of the fluxonium qubit are logically mapped to a ground state and to a first excited state of energy states enabled by a configuration of the fluxonium hardware components;
performing readout of the fluxonium qubit, wherein said performing the readout comprises:
emitting a control sequence, causing a signal, corresponding to quantum information stored in the fluxonium qubit subsequent to said performance of the quantum gate, to be transmitted through a quantum metamaterial; and
providing the signal to a classical measurement device.

18. The method of claim 17, wherein:
the fluxonium hardware components are dispersively coupled to the quantum metamaterial through a readout resonator; and
said emitting the control sequence comprises driving the readout resonator at a frequency corresponding to a resonance frequency of the readout resonator, wherein the resonance frequency is within a passband of the quantum metamaterial and causes the signal to be transmitted through the quantum metamaterial.

19. The method of claim 17, wherein:
the fluxonium hardware components are coupled to the quantum metamaterial; and
said emitting the control sequence comprises driving the fluxonium hardware components at a frequency corresponding to a transition frequency between the ground state and a third excited state of the energy states enabled by the configuration of the fluxonium hardware components, wherein the transition frequency is within a passband of the quantum metamaterial, and causes the signal to be transmitted through the quantum metamaterial using resonance fluorescence.

20. The method of claim 19, further comprising:
resetting, subsequent to said performing the readout, the fluxonium qubit into the ground state, wherein said resetting comprises:
emitting another control sequence comprising multiple frequencies, wherein one or more of the multiple frequencies causes a populated energy state of the energy states enabled by the configuration of the fluxonium hardware components to fluoresce to the ground state.
